(19) United States
(12) Patent Application Publication
(10) Pub. No.: US 2003/0103367 A1
(43) Pub. Date: Jun. 5, 2003

(54) QUANTUM DOT-BASED MAGNETIC RANDOM ACCESS MEMORY (MRAM) AND METHOD FOR MANUFACTURING SAME

(75) Inventors: Gabriel Aeppli, Princeton, NJ (US); David J. Norris, Minneapolis, MN (US); Christophe Renner, Plainsboro, NJ (US); Yeong-Ah Soh, Piscataway, NJ (US)

Correspondence Address: PHILIP J FEIG, NEC RESEARCH INSTITUTE INC, 4 INDEPENDENCE WAY, PRINCETON, NJ, 08540

(73) Assignee: NEC Research Institute, Inc., Princeton, NJ

(21) Appl. No.: 09/998,120

(22) Filed: Nov. 30, 2001

(51) Int. Cl. G11C 11/18

(52) U.S. Cl. 365/9; 257/9

(57) ABSTRACT

A magnetic random access memory (MRAM) cell is provided. The magnetic random access memory cell comprises an insulating substrate, an electrically conductive base line provided on the insulating substrate, at least one magnetic quantum dot attached to the base line, and an electrically conductive top line provided across the at least one magnetic quantum dot in a direction transverse to the base line. A junction is thereby formed between the base line and the top line. At least one of the base line and the top line comprise a magnetic material. A method for manufacturing the magnetic random access memory cell is also provided. In addition, an array of magnetic random access memory cells is provided, as well as a method for manufacturing same.

### FIELD OF THE INVENTION

The present invention relates to the field of non-volatile data storage, and in particular to quantum dot-based magnetic random access memory (“MRAM”).

### BACKGROUND OF THE INVENTION

There are many schemes for magnetic random access memory, and these generally involve readout of the magnetic states of metals via electron tunneling through barrier oxides formed between those metals and other metals needed to carry currents to the edge of the device. Perhaps the most prominent work of this type has been that of S. S. P. Parkin et al., “Exchange-biased magnetic tunnel junctions and application to nonvolatile magnetic random access memory,” J. Appl. Phys., vol. 85, pp. 5828-5833 (1999). Recently, there has been a demonstration of spin-dependent electron tunneling through part of an array of magnetic nanometer-scale quantum dots (small metallic Co crystals). See C. T. Black et al., “Spin-Dependent Tunneling in Self-Assembled Cobalt-Nanocrystal Superlattices,” Science, vol. 290, pp. 1131-1134 (2000).

Typical prior art proposals for magnetic random access memory are flat layers of ferromagnetic metals, deposited under very controlled vacuum conditions, separated by an insulating barrier. Fabrication of such devices in large numbers and at high densities with reproducible performance is difficult. This is caused by variations in the material interfaces inside the device, which lead to variations in electrical current during memory readout. Further, prior art devices suffer from variance in the magnetic characteristics of individual memory cells (or “bits”).

### SUMMARY OF THE INVENTION

The present invention provides an inexpensive, high-density, non-volatile random access memory device. Magnetic information is stored not in thin metallic films, as in conventional MRAM devices, but instead in magnetic quantum dots prepared chemically. The quantum dots, or larger collections of quantum dots, may be located at the junctions of a two-dimensional memory array defined by a grid of crossed nanowires used for reading and writing the magnetic states of the quantum dots.

Thus, a magnetic random access memory (MRAM) cell is provided. The magnetic random access memory cell comprises an insulating substrate, an electrically conductive base line provided on the insulating substrate, at least one magnetic quantum dot attached to the base line, and an electrically conductive top line provided across the at least one magnetic quantum dot in a direction transverse to the base line. A junction is thereby formed between the base line and the top line. At least one of the base line and the top line comprise a magnetic material. A method for manufacturing a magnetic random access memory cell is also provided.

In addition, an array of magnetic random access memory cells is provided. The array of magnetic random access memory cells comprises an insulating substrate and a plurality of electrically conductive base lines provided on the insulating substrate, wherein a plurality of memory cell sites are disposed along each base line. At least one magnetic quantum dot is attached to the base line at each memory cell site. A plurality of electrically conductive top lines are also provided, wherein a top line is provided across the at least one magnetic quantum dot at each memory cell site and in a direction transverse to the base lines, thereby forming a junction between one base line and one top line at each memory cell site. The base lines and/or the top lines comprise a magnetic material. A method for manufacturing an array of magnetic random access memory cell is also provided.

### BRIEF DESCRIPTION OF THE DRAWINGS

FIG. 1A is a plan view of a single bit quantum dot-based MRAM memory cell constructed in accordance with the present invention;

FIG. 1B is an elevation view of a single bit quantum dot-based MRAM memory cell constructed in accordance with the present invention;

FIG. 2 is a plan view of a quantum dot-based MRAM memory cell array constructed in accordance with the present invention; and

FIGS. 3A-3F illustrate the fabrication of an MRAM memory cell in accordance with the present invention, in which each figure includes both a plan view in the upper-portion of each figure and a corresponding elevation view of the same apparatus in the lower portion of each figure.

### DETAILED DESCRIPTION OF THE PREFERRED EMBODIMENTS

Generally speaking, the invention includes a proposal for a single memory cell, and a procedure for assembling an array of such devices onto a substrate for a high-density magnetic memory. The starting point for both the single memory cell and the array are magnetic quantum dots, small nanometer-scale crystals (also called nanocrystals) of magnetic material, prepared in solution and typically highly monodisperse with well-controlled radii. The surfaces of the nanocrystals are coated with organic molecules that act as a “surface cap” or “surface passivation” to prevent the agglomeration of the particles into larger particles.

The quantum dots utilized in the present invention are magnetic, and preferably ferromagnetic, which means they act as magnetic dipoles. A single quantum dot represents the smallest bit size that can be achieved using the devices of the present invention. Information may be encoded in the magnetization of the nanocrystal. Further, since the quantum dots can be induced to aggregate to form regular arrays of quantum dots that are physically distinct but closely packed, information can also be encoded in the magnetization of a collection of magnetic quantum dots.

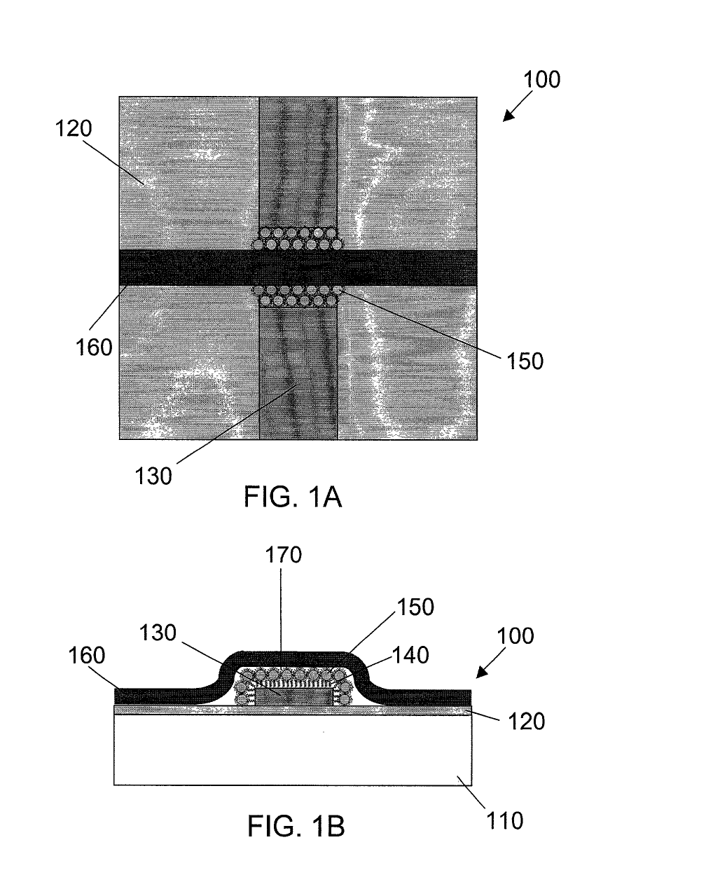

FIG. 1 illustrates a single bit memory cell 100 manufactured in accordance with the present invention. Memory cell 100 includes an insulating substrate 110, such as a silicon wafer, for example, upon which is preferably formed an oxide layer 120. A base line (nanowire) 130, preferably comprised of gold, is provided on the oxide layer 120. One or more magnetic quantum dots 150 is attached to base line 130 using organic linker molecules 140, the ends of each of which are attachable to both the base line 130 and a magnetic quantum dot 150, respectively. A top line (nanowire) 160, preferably comprised of cobalt, is provided across the magnetic quantum dots 150 in a direction transverse to base line 130. The angle made between the base line 130 and top line 160 may be any angle, so long as they are not parallel. A junction 170 is thereby created between base line 130 and top line 160.

It should be noted that while FIG. 1 demonstrates a device that utilizes a plurality of magnetic quantum dots 150 in the junction 170, the memory cells of the present invention also encompass devices, similar to that in FIG. 1, wherein only a single magnetic quantum dot 150 is present in the junction 170.

Each magnetic quantum dot is a nanocrystal and may be prepared by conventional means as known in the art. The magnetic quantum dots are typically 3-10 nm in diameter. Thus, a typical collection of 10 dots by 10 dots in the junction 170 will provide a junction of approximately 100 nm×100 nm. The base line 130 and top line 160 are preferably nanowires having a width of about 10 nm to 100 nm.

The magnetic quantum dots 150 function as a memory by virtue of their magnetic polarization being up or down, which preferably correspond to logic states zero and one, respectively. If sufficient current of a given polarity is passed through the base line 130 underneath the magnetic quantum dots 150, a magnetic field which ensures a particular magnetic polarity will be imposed, thus changing the magnetization of the magnetic quantum dots 150 and writing the desired state into the single bit memory cell 100. The state of the single bit memory cell 100 can be read via a measurement of the electrical resistance of the magnetic quantum dots 150, established by applying a current between the top line 160 and the base line 130. The electrical resistance of the magnetic quantum dots 150 will be high or low depending on whether the magnetic polarization of the top line 160 is antiparallel or parallel to that of the dot.

At least one of the two lines (base line 130 and top line 160) must be magnetic, although both may be magnetic as well. If neither of the two lines is magnetic, the device will not function. Preferably, the magnetic line or lines is or are ferromagnetic. Both lines must be electrical conductors, and therefore both lines are preferably comprised of metal. There are two constraints on the particular metal which may be used for the lines. The first constraint is that the base line 130 must be capable of anchoring a robust linker molecule. These molecules are used to attach the magnetic quantum dots 150 to the preferably metal surface of the base line 130. Examples of robust linkers are difunctional alkanes such as alkane dithiols, alkane diamines, or other linear molecules that selectively attach one end to the nanocrystal and the other to the surface of base line 130 (for example, a linear alkane with an amine functionality at one end and a thiol functionality at the other end, such that the amine can attach to a magnetic quantum dot such as FePt and the thiol can attach to a metal such as gold). A table of chemical functionalities and the surfaces they attach to can be found in Table 4 of Y. Xia et al., “Soft Lithography,” Angewandte Chemie Int. Ed., vol. 37, pp. 550-575 (1998). By placing two such functionalities at opposite ends of a linker molecule, nanocrystals may be attached to metal surfaces. The second constraint is that the coercive field (that is, the magnetic field required to switch polarization) be substantially larger for the magnetic metal than for the magnetic quantum dots.

Preferable materials for use in fabricating the components of the memory cell devices of the present invention are as follows. The insulating substrate 110 is preferably comprised of silicon. The oxide layer 120 is preferably comprised of silicon dioxide. The organic linker molecules 140, which are used to attach the magnetic quantum dots 150 to the base line 130, are preferably comprised of hexane-dithiol (C₆H₁₄S₂). The magnetic quantum dots 150 preferably comprise FePt quantum dots (or “nanodots”) (see, e.g., S. Sun et al., “Monodisperse FePt Nanoparticles and ferromagnetic FePt nanocrystal superlattices,” Science, vol. 287, pp. 1989-1992 (2001)). The magnetic line or lines (whether base line 130 or top line 160) preferably comprise any ferromagnetic material, including but not limited to the cobalt, iron, and nickel-based alloys as well as various metallic transition metal oxides derived from LaMnO₃. The non-magnetic line, if present (whether base line 130 or top line 160), is preferably comprised of metal, and is most preferably comprised of gold. The base line 130 is preferably affixed by patterning it on the substrate using optical lithography. The top line 160 is preferably affixed by evaporating it across the quantum dots 150 and the substrate. Preferably, base line 130 is non-magnetic while top line 160 is magnetic.

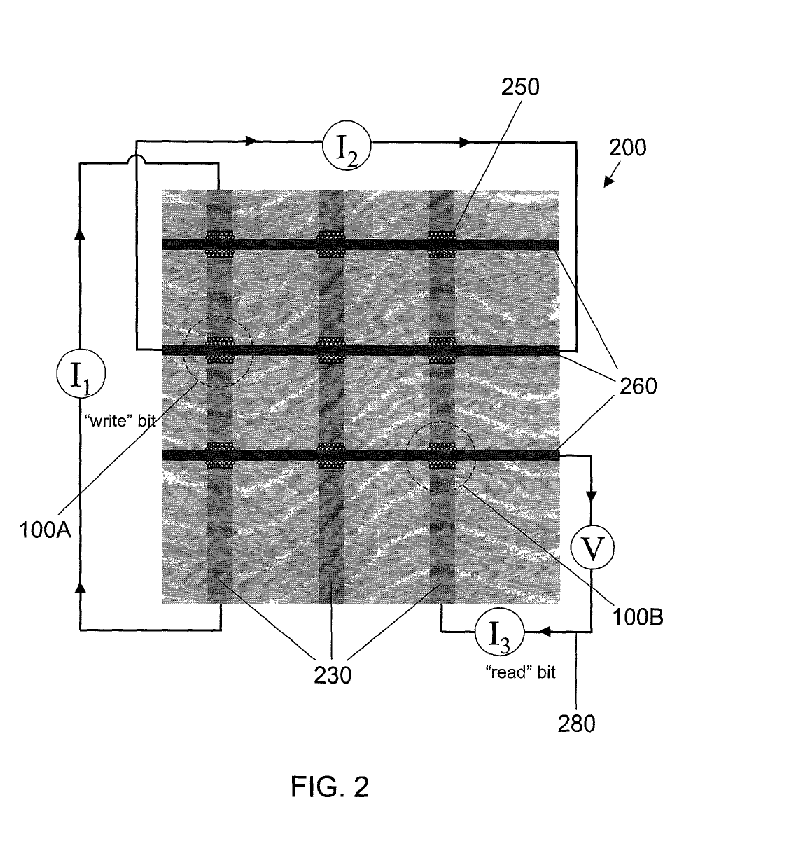

In addition to single bit memory cell devices, the invention also encompasses memory cell arrays. FIG. 2 illustrates a magnetic memory cell array 200 which is generally an array of the single bit memory cells shown in FIG. 1. In this embodiment, the silicon substrate is patterned with a plurality of parallel base lines 230. A plurality of memory cell sites is disposed along each base line, at which one or more magnetic quantum dots 250 are attached to the base line 230 using an organic linker. Likewise, a plurality of transverse top lines 260 are provided. Writing proceeds (as with conventional MRAM arrays) by passing a current through the top line and base line that intersect at the node defining the memory cell whose contents one wishes to specify. Thus, to write the state of memory cell 100A in FIG. 2, electrical currents of the same sign and magnitude I₁ and I₂ are injected as shown in FIG. 2. The setting of the resulting bit depends on the overall sign, meaning for example that a binary “0” would be written by currents I₁=I₂=−1 microamperes, and a binary “1” would be written by currents I₁=I₂=−1 microamperes. The reading operation is accomplished via measurement of the electrical resistance of a circuit completed through the top and base lines intersecting at the memory cell of interest. Thus, to determine the state of memory cell 100B in FIG. 2, a current I₃ is made to flow around loop 280, and the associated voltage V is read. A high voltage corresponds to a high-resistance state, signifying a binary “0”, and a low voltage would corresponds to a low-resistance state, signifying a binary “1”.

The materials requirements for the memory cell array 200 are similar to the single memory cell device 100 described above, with the additional proviso that the magnetization versus field loops for the magnetic quantum dots are sufficiently square so that the vector addition of the magnetic fields from the two crossed nanowires will unambiguously switch the magnetic quantum dots from one state to the other. In addition, the magnetic field from only a single nanowire (such as only the base line or only the top line but not both) should not switch the magnetization.

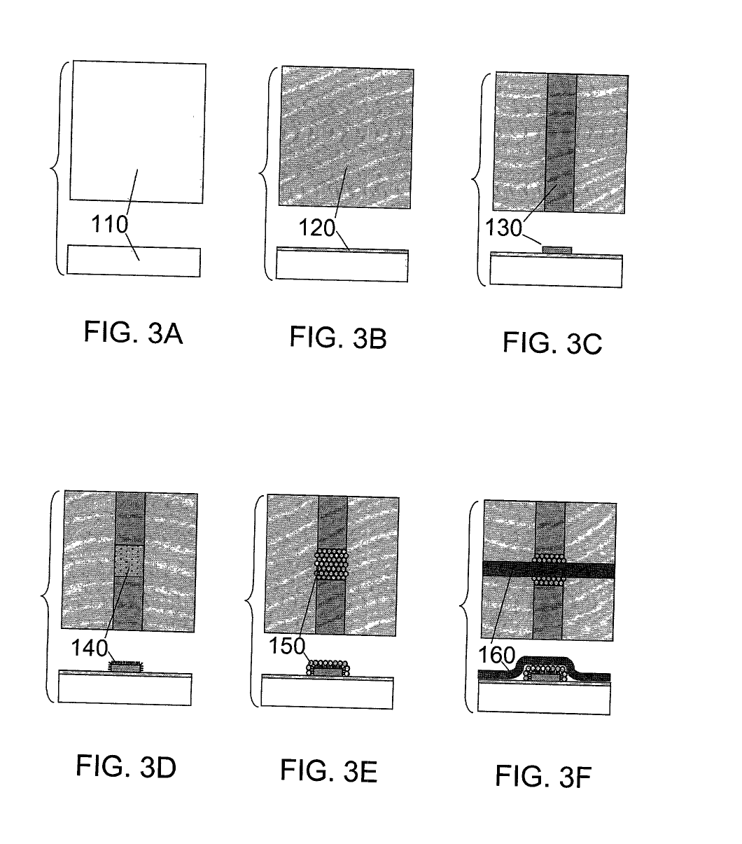

FIGS. 3A-3F illustrate an exemplary method for manufacturing a single bit memory cell or a memory cell array in accordance with the present invention. Each of FIGS. 3A-3F includes both a plan view in the upper-portion of each figure and a corresponding elevation view of the same apparatus in the lower portion of each figure. As shown in FIG. 3A, the insulating substrate 110 is first provided. As shown in FIG. 3B, an oxide layer 120 is then formed on the insulating substrate 110. The oxide layer 120 ensures that subsequent layers are insulated from the substrate 110. The next step as shown in FIG. 3C, is to deposit a base line 130, or a parallel array of base lines 130 in the case of a memory cell array, on the oxide layer 120. These base line or lines 130 are preferably non-magnetic. Once deposited, a layer of organic linker molecules 140 is deposited as shown in FIG. 3D to the areas of the base lines 130 that will eventually become the junction regions 170 as shown in FIG. 1B. This can be achieved by utilizing the known technique of micro-contact printing, which uses soft-lithographic approaches to make a flexible (patterned) rubber stamp that can be coated with linker and then pressed against the base lines. This causes a monolayer of linker molecules to be deposited at predetermined sites on the base lines. (See Xia et al., supra, for a description of soft-lithography and micro-contact printing). Next, magnetic quantum dots 150 are deposited, preferably by dipping the entire device in a solution of magnetic quantum dots, which selectively attach to the linker-coated base lines as shown in FIG. 3E. Finally, lithography is used to deposit a top line 160, or a parallel array of top lines 160 in the case of a memory cell array, as shown in FIG. 3F. These top lines 160 are preferably magnetic and are preferably deposited in a direction transverse, and preferably orthogonal, to the base line or lines 130.

While FIG. 3 shows a close-up view of a single memory cell (single bit device), an array of devices can be made according to the above procedure and as noted above. For example, FIG. 2 shows a 3×3 array of such devices.

It will be evident that the present invention provides for the production of large quantities of magnetic quantum dots with highly reproducible shapes, radii, and coatings using relatively standard chemical means. At the same time, modern lithography permits the cheap fabrication of arrays of metallic lines. The junctions, which are central to most MRAM schemes proposed to date, are formed between chemically reproduced and coated entities (the magnetic quantum dots) and simple metals. The magnetic quantum dots with their coatings can therefore be considered as prefabricated tunneling devices, with well-defined magnetic switching characteristics as well. As a result, a memory cell array can be manufactured according to the present invention using a series of very simple steps, which do not require manufacturing complete tunnel junctions in a vacuum system, and involve only one metal evaporation after the magnetic quantum dots are deposited by wet chemistry.

While there have been described and illustrated herein various magnetic quantum dot-based magnetic random access memory cell devices, it will be apparent to those skilled in the art that further variations and modifications are possible without deviating from the broad teachings and spirit of the invention which shall be limited solely by the scope of the claims appended hereto.

What is claimed is:

1. A magnetic random access memory cell comprising:
an insulating substrate;
an electrically conductive base line provided on the insulating substrate;
at least one magnetic quantum dot attached to the base line; and
an electrically conductive top line provided across the at least one magnetic quantum dot in a direction transverse to the base line, thereby forming a junction between the base line and the top line, wherein at least one of the base line and the top line comprise a magnetic material.

2. The magnetic random access memory cell of claim 1, wherein the top line is provided in a direction perpendicular to the base line.

3. The magnetic random access memory cell of claim 1, wherein both the base line and the top line comprise magnetic materials.

4. The magnetic random access memory cell of claim 1, wherein the magnetic material is a ferromagnetic material.

5. The magnetic random access memory cell of claim 4, wherein the ferromagnetic material is selected from the group consisting of cobalt, iron, nickel-based alloys and metallic transition metal oxides derived from LaMnO₃.

6. The magnetic random access memory cell of claim 1, wherein one of the base line and the top line comprises a non-magnetic material.

7. The magnetic random access memory cell of claim 6, wherein the non-magnetic material is a metal.

8. The magnetic random access memory cell of claim 6, wherein the non-magnetic material is gold.

9. The magnetic random access memory cell of claim 1, wherein the at least one magnetic quantum dot is attached to the base line by an organic linker.

10. The magnetic random access memory cell of claim 9, wherein the organic linker is selected from the group consisting of difunctional alkanes such as alkane dithiols, alkane diamines.

11. The magnetic random access memory cell of claim 9, wherein the base line is a metal, and wherein the organic linker is a linear alkane with an amine functionality at one end and a thiol functionality at the other end, such that the amine attaches to a magnetic quantum dot and the thiol attaches to the metal base line.

12. The magnetic random access memory cell of claim 9, wherein the organic linker is hexane-dithiol (C₆H₁₄S₂).

13. The magnetic random access memory cell of claim 1, wherein the at least one magnetic quantum dot is a ferromagnetic quantum dot.

14. The magnetic random access memory cell of claim 1, wherein the at least one magnetic quantum dot comprises an FePt quantum dot.

15. The magnetic random access memory cell of claim 1, wherein the insulating substrate includes an oxide layer such that the base line is provided on the oxide layer.

16. A method for manufacturing a magnetic random access memory cell, the method comprising:
providing an electrically conductive base line on an insulating substrate;
attaching at least one magnetic quantum dot to the base line; and
providing an electrically conductive top line across the at least one magnetic quantum dot in a direction transverse to the base line, thereby forming a junction between the base line and the top line, wherein at least one of the base line and the top line comprise a magnetic material.

17. The method of claim 16, wherein the top line is provided in a direction perpendicular to the base line.

18. The method of claim 16, wherein both the base line and the top line comprise magnetic materials.

19. The method of claim 16, wherein the magnetic material is a ferromagnetic material.

20. The method of claim 19, wherein the ferromagnetic material is selected from the group consisting of cobalt, iron, nickel-based alloys and metallic transition metal oxides derived from LaMnO₃.

21. The method of claim 16, wherein one of the base line and the top line comprises a non-magnetic material.

22. The method of claim 21, wherein the non-magnetic material is a metal.

23. The method of claim 21, wherein the non-magnetic material is gold.

24. The method of claim 16, wherein the at least one magnetic quantum dot is attached to the base line by an organic linker.

25. The method of claim 24, wherein the organic linker is selected from the group consisting of difunctional alkanes such as alkane dithiols, alkane diamines.

26. The method of claim 24, wherein the base line is a metal, and wherein the organic linker is a linear alkane with an amine functionality at one end and a thiol functionality at the other end, such that the amine attaches to a magnetic quantum dot and the thiol attaches to the metal base line.

27. The method of claim 24, wherein the organic linker is hexane-dithiol (C₆H₁₄S₂).

28. The method of claim 16, wherein the at least one magnetic quantum dot is a ferromagnetic quantum dot.

29. The method of claim 16, wherein the at least one magnetic quantum dot comprises an FePt quantum dot.

30. The method of claim 16, further comprising the step of forming an oxide layer on a substrate to provide the insulating substrate.

31. The method of claim 16, wherein the base line is provided on the insulating substrate by patterning the base line on the insulating substrate using optical lithography.

32. The method of claim 16, wherein the top line is provided across the at least one magnetic quantum dot by evaporation.

33. An array of magnetic random access memory cells, the array comprising:
an insulating substrate;
a plurality of electrically conductive base lines provided on the insulating substrate, wherein a plurality of memory cell sites are disposed along each base line;
at least one magnetic quantum dot attached to the base line at each memory cell site; and
a plurality of electrically conductive top lines, wherein a top line is provided across the at least one magnetic quantum dot at each memory cell site and in a direction transverse to the base lines, thereby forming a junction between one base line and one top line at each memory cell site, and wherein the base lines and/or the top lines comprise a magnetic material.

34. The array of magnetic random access memory cells of claim 33, wherein the top lines are provided in a direction perpendicular to the base lines.

35. The array of magnetic random access memory cells of claim 33, wherein both the base lines and the top lines comprise magnetic materials.

36. The array of magnetic random access memory cells of claim 33, wherein the magnetic material is a ferromagnetic material.

37. The array of magnetic random access memory cells of claim 36, wherein the ferromagnetic material is selected from the group consisting of cobalt, iron, nickel-based alloys and metallic transition metal oxides derived from LaMnO₃.

38. The array of magnetic random access memory cells of claim 33, wherein the base lines comprise a non-magnetic material.

39. The array of magnetic random access memory cells of claim 38, wherein the non-magnetic material is a metal.

40. The array of magnetic random access memory cells of claim 38, wherein the non-magnetic material is gold.

41. The array of magnetic random access memory cells of claim 33, wherein the top lines comprise a non-magnetic material.

42. The array of magnetic random access memory cells of claim 41, wherein the non-magnetic material is a metal.

43. The array of magnetic random access memory cells of claim 41, wherein the non-magnetic material is gold.

44. The array of magnetic random access memory cells of claim 33, wherein the at least one magnetic quantum dot at each memory cell site is attached to the base line by an organic linker.

45. The array of magnetic random access memory cells of claim 44, wherein the organic linker is selected from the group consisting of difunctional alkanes such as alkane dithiols, alkane diamines.

46. The array of magnetic random access memory cells of claim 44, wherein the base lines are metal, and wherein the organic linker is a linear alkane with an amine functionality at one end and a thiol functionality at the other end, such that the amine attaches to a magnetic quantum dot and the thiol attaches to the metal base line.

47. The array of magnetic random access memory cells of claim 44, wherein the organic linker is hexane-dithiol (C₆H₁₄S₂).

48. The array of magnetic random access memory cells of claim 33, wherein each magnetic quantum dot is a ferromagnetic quantum dot.

49. The array of magnetic random access memory cells of claim 33, wherein each magnetic quantum dot comprises an FePt quantum dot.

50. The array of magnetic random access memory cells of claim 33, wherein the insulating substrate includes an oxide layer such that the base line is provided on the oxide layer.

51. A method for manufacturing an array of magnetic random access memory cells, the method comprising:
providing a plurality of electrically conductive base lines on an insulating substrate, wherein a plurality of memory cell sites are disposed along each base line;
attaching at least one magnetic quantum dot to the base line at each memory cell site; and
providing a plurality of electrically conductive top lines, wherein a top line is provided across the at least one magnetic quantum dot at each memory cell site and in a direction transverse to the base lines, thereby forming a junction between one base line and one top line at each memory cell site, and wherein the base lines and/or the top lines comprise a magnetic material.

52. The method of claim 51, wherein the top lines are provided in a direction perpendicular to the base lines.

53. The method of claim 51, wherein both the base lines and the top lines comprise magnetic materials.

54. The method of claim 51, wherein the magnetic material is a ferromagnetic material.

55. The method of claim 54, wherein the ferromagnetic material is selected from the group consisting of cobalt, iron, nickel-based alloys and metallic transition metal oxides derived from LaMnO₃.

56. The method of claim 51, wherein the base lines comprise a non-magnetic material.

57. The method of claim 56, wherein the non-magnetic material is a metal.

58. The method of claim 56, wherein the non-magnetic material is gold.

59. The method of claim 51, wherein the top lines comprise a non-magnetic material.

60. The method of claim 59, wherein the non-magnetic material is a metal.

61. The method of claim 59, wherein the non-magnetic material is gold.

62. The method of claim 51, wherein the at least one magnetic quantum dot at each memory cell site is attached to the base line by an organic linker.

63. The method of claim 62, wherein the organic linker is selected from the group consisting of difunctional alkanes such as alkane dithiols, alkane diamines.

64. The method of claim 62, wherein the base lines are metal, and wherein the organic linker is a linear alkane with an amine functionality at one end and a thiol functionality at the other end, such that the amine attaches to a magnetic quantum dot and the thiol attaches to the metal base line.

65. The method of claim 62, wherein the organic linker is hexane-dithiol (C₆H₁₄S₂).

66. The method of claim 51, wherein each magnetic quantum dot is a ferromagnetic quantum dot.

67. The method of claim 51, wherein each magnetic quantum dot comprises an FePt quantum dot.

68. The method of claim 51, further comprising the step of forming an oxide layer on a substrate to provide the insulating substrate.

69. The method of claim 51, wherein the base lines are provided on the insulating substrate by patterning the base lines on the insulating substrate using optical lithography.

70. The method of claim 51, wherein the top lines are provided across the at least one magnetic quantum dot at each memory cell site by evaporation.
